(19) United States
(12) Patent Application Publication
(10) Pub. No.: US 2026/0238215 A1
(43) Pub. Date: Aug. 13, 2026

(54) SEMICONDUCTOR DEVICE

(71) Applicant: RENESAS ELECTRONICS CORPORATION, Tokyo (JP)

(72) Inventor: Toshihiko FUNAKI, Tokyo (JP)

(21) Appl. No.: 19/426,330

(22) Filed: Dec. 19, 2025

(30) Foreign Application Priority Data
Feb. 12, 2025 (JP) 2025-020698

(51) Int. Cl. H03L 7/081; H03L 7/089

(52) U.S. Cl. CPC H03L 7/0818; H03L 7/089

(57) ABSTRACT

Improve communication performance between semiconductor devices. The phase detector PHD outputs N-bit phase detection data PD by latching the N-phase clock signals at the edge of the data signal. The phase judgement circuit outputs a phase selection signal indicating the selection of one of the N phases based on the phase detection data PD. The timing adjustment circuit outputs a delayed phase selection signal by delaying the phase selection signal by a delay time determined for each selected phase. The clock selection circuit selects and outputs one of the N-phase clock signals according to the delayed phase selection signal. The data latch circuit latches the data signal with the clock signal selected by the clock selection circuit.

### CROSS-REFERENCE TO RELATED APPLICATIONS

The disclosure of Japanese Patent Application No. 2025-020698 filed on February 12, 2025, including the specification, drawings and abstract is incorporated herein by reference in its entirety.

### BACKGROUND

The present invention relates to a semiconductor device, for example, a semiconductor device equipped with a serial interface.

There are disclosed techniques listed below.

[Patent Document 1] Japanese Unexamined Patent Application Publication No. 2003-224551

Patent Document 1 discloses a clock data recovery circuit that accurately recovers high-speed clock and data. The clock data recovery circuit includes an edge detection circuit, a clock selection signal generation circuit, and a clock selection circuit. The edge detection circuit uses the receiver output as a clock and generates edge position information. The clock selection signal generation circuit generates a clock selection signal based on edge position information. The clock selection circuit selects a recovered clock from the clock group according to the clock selection signal.

### SUMMARY

Recently, technology called Chiplet has attracted attention. Chiplet is a technology that combines multiple chips to be treated as a single chip. When using Chiplet, communication between chips is conducted based on the UCIe (Universal Chiplet Interconnect Express) standard, which is an open standard. However, the UCIe standard is a standard for achieving relatively high-performance communication. Therefore, depending on the product, it may result in over-specification, including cost.

It is conceivable to use a general serial interface method, represented by SerDes, for communication between chips. In such a serial interface method, a clock data recovery circuit as shown in Patent Document 1 is used to easily achieve communication of medium performance or lower. However, especially considering the application to Chiplet, the clock data recovery circuit is to improve communication performance between semiconductor devices. Furthermore, a mechanism to achieve lower cost and shorter TAT (Turn Around Time) have been awaited.

The embodiments described later have been made in view of such issues, and other problems and novel features will become apparent from the description herein and the accompanying drawings.

A semiconductor device according to one embodiment includes a phase detector, a phase judgement circuit, a timing adjustment circuit, a clock selection circuit, and a data latch circuit. The phase detector receives a data signal and N-phase clock signals having phases different from each other, and outputs N-bit phase detection data by latching the N-phase clock signals at the edge of the data signal. The phase judgement circuit selects one of the N phases based on the N-bit phase detection data and outputs a phase selection signal representing the phase to be selected. The timing adjustment circuit receives the phase selection signal and output a delayed phase selection signal by delaying the phase selection signal by a delay time determined for each phase to be selected. The clock selection circuit receives the N-phase clock signals and selects and outputs one of the N-phase clock signals according to the delayed phase selection signal. The data latch circuit latches the data signal with the clock signal from the clock selection circuit.

According to the embodiment, communication performance between semiconductor devices can be improved.

### BRIEF DESCRIPTION OF THE DRAWINGS

FIG. 1 is a schematic diagram showing a configuration example of a clock data recovery circuit mounted on a semiconductor device according to one embodiment.

FIG. 2 is a schematic diagram showing an operation example of the timing adjustment circuit in FIG. 1.

FIG. 3 is a circuit block diagram showing a configuration example of the main part of the timing adjustment circuit in FIG. 1.

FIG. 4 is a supplementary diagram for explaining an operation example of the timing adjustment circuit shown in FIG. 3.

FIG. 5 is a supplementary diagram for explaining an operation example of the timing adjustment circuit shown in FIG. 3.

FIG. 6 is a timing chart showing an operation example of the timing adjustment circuit shown in FIG. 3.

FIG. 7 is a circuit diagram showing a detailed configuration example of the phase detector in FIG. 1.

FIG. 8 is a timing chart showing an operation example of the majority decision circuit in FIG. 1.

FIG. 9 is a schematic diagram showing an operation example of the majority decision circuit in FIG. 1.

FIG. 10 is a schematic diagram showing an operation example of the metastable removal circuit in FIG. 1.

FIG. 11 is a table showing an example of input/output operation of the metastable removal circuit in FIG. 1.

FIG. 12 is a schematic diagram showing an operation example of the main part when using an analog circuit method in a clock data recovery circuit as a first comparative example.

FIG. 13 is a schematic diagram showing a configuration example and an operation example of the main part when using a digital circuit method in a clock data recovery circuit as a second comparative example.

FIG. 14 is a schematic diagram showing the first problem in a clock data recovery circuit using a digital circuit method.

FIG. 15 is a schematic diagram showing the second problem in a clock data recovery circuit using a digital circuit method.

FIG. 16 is a schematic diagram showing the third problem in a clock data recovery circuit using a digital circuit method.

### DETAILED DESCRIPTION

In the following embodiments, for convenience, explanations may be divided into multiple sections or embodiments when necessary. However, unless specifically stated otherwise, they are not unrelated to each other, and one is related to the other as a modification, detail, supplementary explanation, etc., of part or all. Also, when referring to the number of elements (including the number, numerical values, quantities, ranges, etc.), unless specifically stated or clearly limited to a specific number in principle, it is not limited to that specific number. That is, the number of elements may be equal to or greater than or equal to or less than the specific number.

In the embodiments, the constituent elements (including element steps) are not necessarily essential unless specifically stated or considered obviously essential in principle. Similarly, when referring to the shapes, positional relationships, etc., of components, unless specifically stated or considered obviously not so in principle, it includes those substantially approximate or similar to those shapes, etc. The same applies to the above numerical values and ranges.

Hereinafter, embodiments of the present invention are described in detail with reference to the drawings. In all the drawings for explaining the embodiments, the same members are denoted by the same reference numerals in principle, and repetitive descriptions thereof are omitted.

### Overview of Semiconductor Device

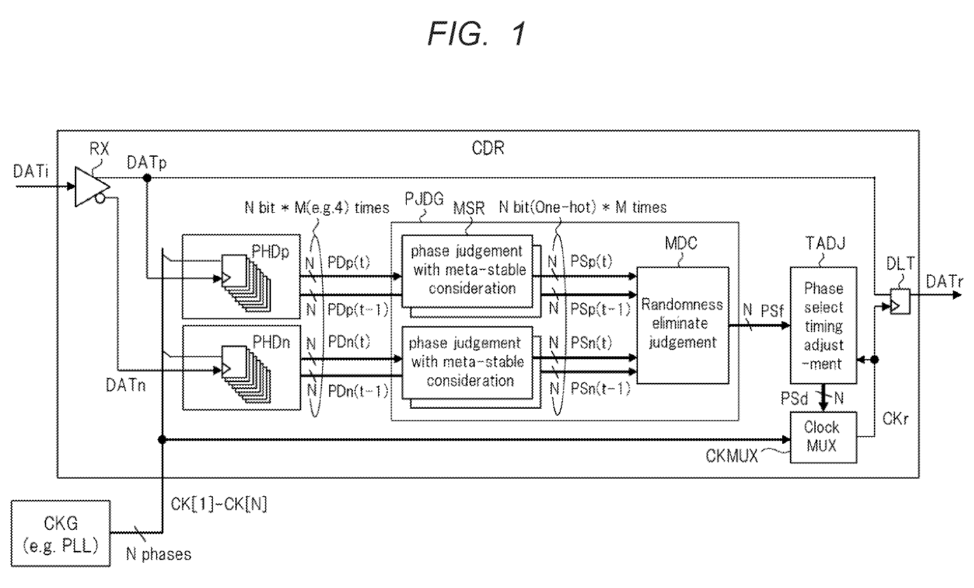

FIG. 1 is a schematic diagram showing a configuration example of a clock data recovery circuit CDR mounted on a semiconductor device according to one embodiment. A semiconductor device according to one embodiment is composed of, for example, a single semiconductor chip. The semiconductor device includes a serial interface for data communication with other semiconductor devices. The clock data recovery circuit CDR shown in FIG. 1 is included in the receiving circuit of the serial interface.

The clock data recovery circuit CDR shown in FIG. 1 includes a data receiver RX and a data latch circuit DLT. Furthermore, the clock data recovery circuit CDR includes two phase detectors PHDp, PHDn, a phase judgement circuit PJDG, a timing adjustment circuit TADJ, and a clock selection circuit CKMUX. Also, a clock generator CKG is provided inside or outside the clock data recovery circuit CDR. In this disclosure, the two phase detectors PHDp, PHDn are collectively referred to as the phase detector PHD.

The clock generator CKG generates N-phase clock signals CK[1]-CK[N] that are different in phases from each other by using, for example, a PLL (Phase Locked Loop) circuit. N is an integer of 2 or more and is usually an even number determined by a power of 2. The embodiment is described using a case where N = 8 as an example. In this case, the 8-phase clock signals CK[1]-CK[8] have phases different from each other by 45[deg]. In this disclosure, the clock signals of each phase are collectively referred to as clock signal CK.

The data receiver RX receives a data signal DATi from outside the semiconductor device, for example. Then, the data receiver RX outputs the positive polarity data signal DATp, which is the same polarity as the received data signal DATi, and the negative polarity data signal DATn, which is the opposite polarity. The data receiver RX outputs the two data signals DATp, DATn, such that the phase difference between the two data signals DATp, DATn is 180[deg], in order to prevent phase shift. In this disclosure, the two data signals DATp, DATn are collectively referred to as data signal DAT.

It is described an outline of the phase detector PHD, phase judgement circuit PJDG and timing adjustment circuit TADJ, here. The details will be described later. The phase detector PHD receives the data signal DAT and the N-phase clock signals CK[1]-CK[8]. The phase detector PHD outputs N-bit phase detection data PD by latching the N-phase clock signals CK[1]-CK[8] at the edge of the data signal DAT.

In this example, the phase detector PHDp latches the N-phase clock signals CK[1]-CK[8] at the rising edge of the positive polarity data signal DATp. Then, the phase detector PHDp outputs N-bit phase detection data PDp as a latch result. On the other hand, the phase detector PHDn latches the N-phase clock signals CK[1]-CK[8] at the rising edge of the negative polarity data signal DATn. That is, the phase detector PHDn equivalently latches the N-phase clock signals CK[1]-CK[8] at the falling edge of the positive polarity data signal DATp. Then, the phase detector PHDn outputs N-bit phase detection data PDn, as a latch result.

The phase judgement circuit PJDG receives the N-bit phase detection data PD from the phase detector PHD. The phase judgement circuit PJDG determines one phase to be selected out of the N phases based on the N-bit phase detection data PD. Then, the phase judgement circuit PJDG outputs an N-bit phase selection signal PSf indicating a phase to be selected. The timing adjustment circuit TADJ receives the N-bit phase selection signal PSf and adds a delay time to it. The delay time is determined for each selected phase. Thus, the timing adjustment circuit TADJ outputs an N-bit delayed phase selection signal PSd at a timing corresponding to the selected phase.

The clock selection circuit CKMUX receives the N-phase clock signals CK[1]-CK[8] from the clock generator CKG and the N-bit delayed phase selection signal PSd from the timing adjustment circuit TADJ. The clock selection circuit CKMUX selects and outputs one clock signal CKr out of the N-phase clock signals CK[1]-CK[8] according to the N-bit delayed phase selection signal PSd. The output clock signal CKr becomes a recovered clock signal. The data latch circuit DLT outputs a data signal DATr by latching the positive-side data signal DATp in response to the clock signal CKr from the clock selection circuit CKMUX. The output data signal DATr becomes the recovered data signal.

By providing such a clock data recovery circuit CDR, it is sufficient to provide data wiring for serial data communication between a plurality of semiconductor devices, and clock wiring is unnecessary. Therefore, for example, by using the clock data recovery circuit CDR for inter-chip communication in Chiplet, miniaturization and cost reduction of Chiplet products can be achieved. However, in Chiplet products, inter-chip communication performance can become a bottleneck in product performance. Therefore, the clock data recovery circuit CDR requires a mechanism to further improve inter-chip communication performance.

### Comparative Example of Clock Data Recovery Circuit and Its Problems

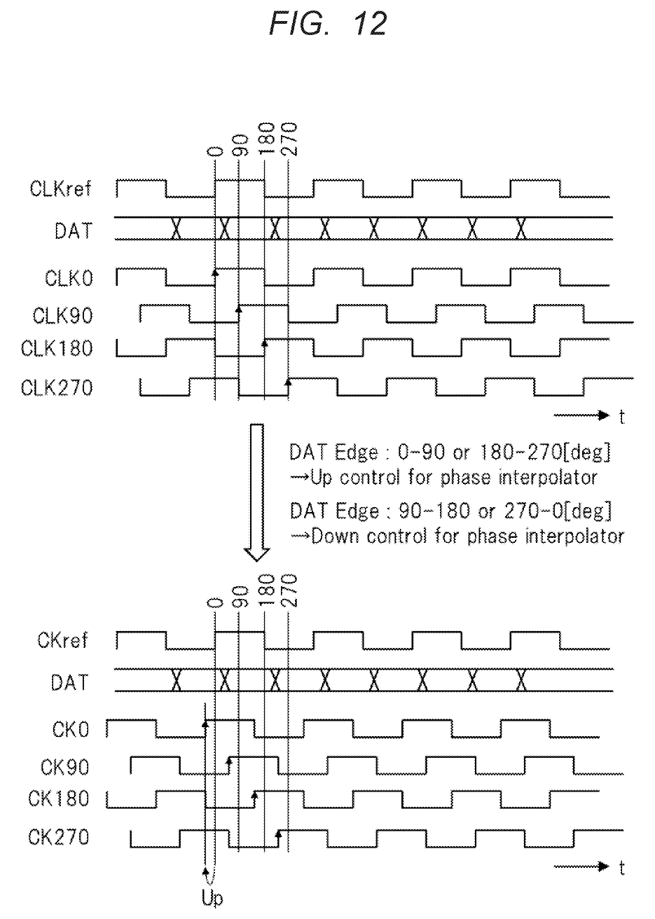

Here, as circuit methods for the clock data recovery circuit, analog circuit method and digital circuit method are generally known. FIG. 12 is a schematic diagram showing an example of the operation of the main part when using an analog circuit method in a clock data recovery circuit as a first comparative example. A clock data recovery circuit using an analog circuit method includes a phase interpolation circuit. As shown in FIG. 12, the phase interpolation circuit generates, for example, four-phase clock signals CK0, CK90, CK180, CK270 from a reference clock signal CKref. The clock data recovery circuit latches the data signal DAT at the rising edges of the four-phase clock signals CK0, CK90, CK180, CK270.

The clock data recovery circuit determines, based on the latch result, between which of the four-phase clock signals CK0, CK90, CK180, CK270 the edge of the data signal DAT is located. As shown in FIG. 12, the clock data recovery circuit performs up control when the edge of the data signal DAT is between 0-90[deg] or 180-270[deg]. In up control, the phase interpolation circuit advances the phase of the four-phase clock signals CK0, CK90, CK180, CK270 by a predetermined amount.

On the other hand, the clock data recovery circuit performs down control when the edge of the data signal DAT is between 90-180[deg] or 270-0[deg]. In down control, the phase interpolation circuit delays the phase of the four-phase clock signals CK0, CK90, CK180, CK270 by a predetermined amount. In this way, the phase interpolation circuit is configured as an analog circuit capable of seamlessly adjusting the phase. Therefore, the phase adjustment resolution is high. However, in general, analog circuits require design for each product and a significant amount of design work. Therefore, in the analog circuit method, an increase in cost and an extension of TAT (Turnaround Time) may occur.

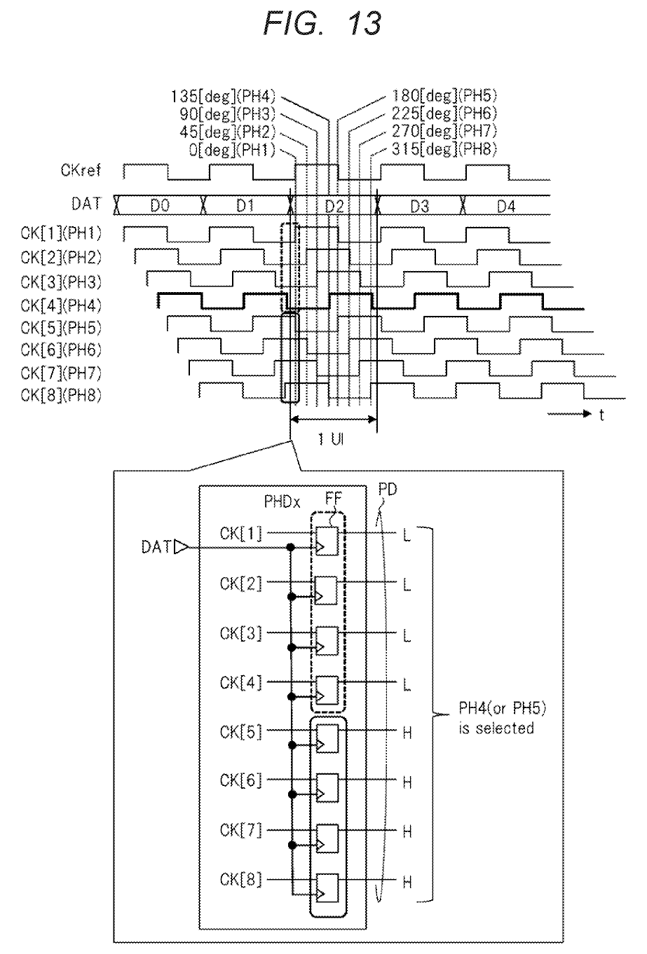

FIG. 13 is a schematic diagram showing an example of the configuration and operation of the main parts when using a digital circuit method in a clock data recovery circuit, which serves as a second comparative example. The clock data recovery circuit using the digital circuit method is equipped with a phase detector PHDx, as shown in FIG. 13. The phase detector PHDx receives N-phase clock signals, here 8-phase clock signals CK[1]-CK[8], generated from the reference clock signal CKref. Then, the phase detector PHDx uses 8 flip-flops FF to latch the 8-phase clock signals CK[1]-CK[8] at the rising edge of the data signal DAT.

In the operational example shown in FIG. 13, the latch result of clock signal CK[4] with phase PH4, namely the phase detection data PD, is “L”. The phase detection data PD of the clock signal CK[5] with phase PH5 is “H”. The clock data recovery circuit selects, for example, phase PH4 whose latch result indicates “L” out of phases whose latch results change from “L” to “H”. As shown in FIG. 13, the selected clock signal CK[4] has a rising edge approximately in the middle of the data window of the data signal DAT. In another cases, the clock data recovery circuit may select the phase PH5 whose latch result indicates “H” out of phases whose latch results change from “L” to “H”. In this disclosure, each phase is collectively referred to as phase PH.

Thus, the clock data recovery circuit using the digital circuit method selects one phase of the clock signal out of the N-phase clock signals CK based on the detection result of the phase detector PHDx. Such a clock data recovery circuit is composed of digital circuits. Therefore, individual product design is unnecessary, and the design workload is less compared to using analog circuits. As a result, cost reduction and TAT shortening can be achieved.

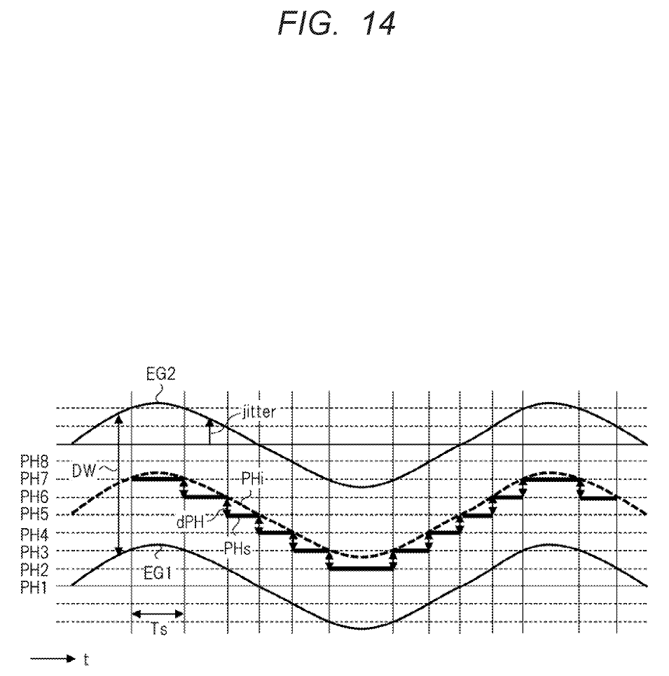

However, when using digital circuit method, for example, the following first to third problems may arise. FIG. 14 is a schematic diagram showing the first problem in the clock data recovery circuit using digital circuit method. FIG. 14 shows the time variations of two adjacent edges EG1 and EG2 in the data signal DAT. The range between the two edges EG1, EG2 becomes the data window DW.

The phase of the two edges EG1, EG2 generally change periodically due to jitter. An ideal clock data recovery circuit follows the periodic changes of these two edges EG1, EG2 and keeps the phase PH of the clock signal CK to be an ideal phase Phi that is located at the center of the data window DW. On the other hand, in an actual clock data recovery circuit using the digital circuit method, the phase PH that is candidate for selection is discrete value.

Therefore, in FIG. 14, the ideal phase PHi is selected for a predetermined time between two adjacent phases PH that have discrete values. Here, the predetermined time is referred to as the selection time Ts. The clock data recovery circuit selects the earlier phase PH from the two adjacent phases PH as the phase PHs at the selected time Ts. As a specific example, the clock data recovery circuit, when the ideal phase PHi is located between phase PH7 and phase PH8, selects the earlier phase PH7 as the phase PHs at the corresponding selection time Ts.

It should be noted that the edges of the data signal DAT occur with a certain frequency due to encoding to maintain DC balance, even when the same data value continues. Therefore, during the selection time Ts in FIG. 14, it is common to obtain phase detection data that are the same value from the phase detector PHDx multiple times.

However, when using such a method, as shown in FIG. 14, a phase error dPH that is equal to difference in phase between each phase PH in maximum occurs can occur between the ideal phase PHi and the selected phase PHs. For example, when using 8 phases PH1-PH8, the maximum phase error dPH is 45(=360/8) [deg].

The phase error dPH causes a decrease in inter-chip communication performance. Specifically, the larger the phase error dPH, the more difficult it becomes to achieve high-speed communication. Moreover, as the phase error dPH increases, the error rate of the recovered data signal, namely the BER (Bit Error Rate), becomes higher. However, the digital circuit method is inherently a method that results in quantization errors. Therefore, the occurrence of phase error dPH itself is unavoidable.

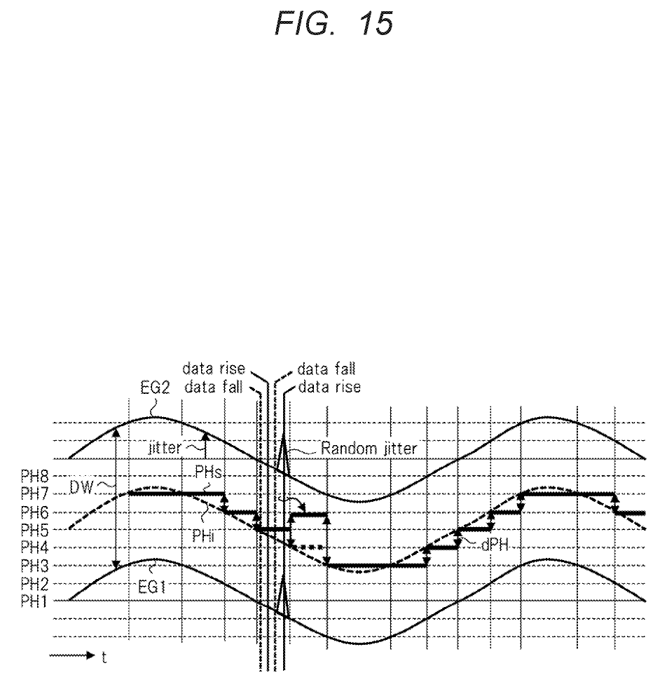

FIG. 15 is a schematic diagram showing the second problem in a clock data recovery circuit using the digital circuit method. In FIG. 15, as in the case of FIG. 14, periodic jitter occurs in the two edges EG1, EG2 of the data signal DAT. In addition, temporary jitter, that is, random jitter, occur in the two edges EG1, EG2 of the data signal DAT.

In the example shown in FIG. 15, the phases of the two edges EG1, EG2 are temporarily delayed by random jitter at a certain time. Accordingly, the clock data recovery circuit selects the phase PH6, which is delayed by two steps, instead of the phase PH4 to be selected. In this way, when random jitter occurs, the phase error dPH described in FIG. 14 can temporarily increase. As a result, inter-chip communication performance may deteriorate. Specifically, when latching the data signal DAT using the selected phase PH6, that is, when obtaining the recovered data signal, errors are likely to occur. As a result, the BER may increase.

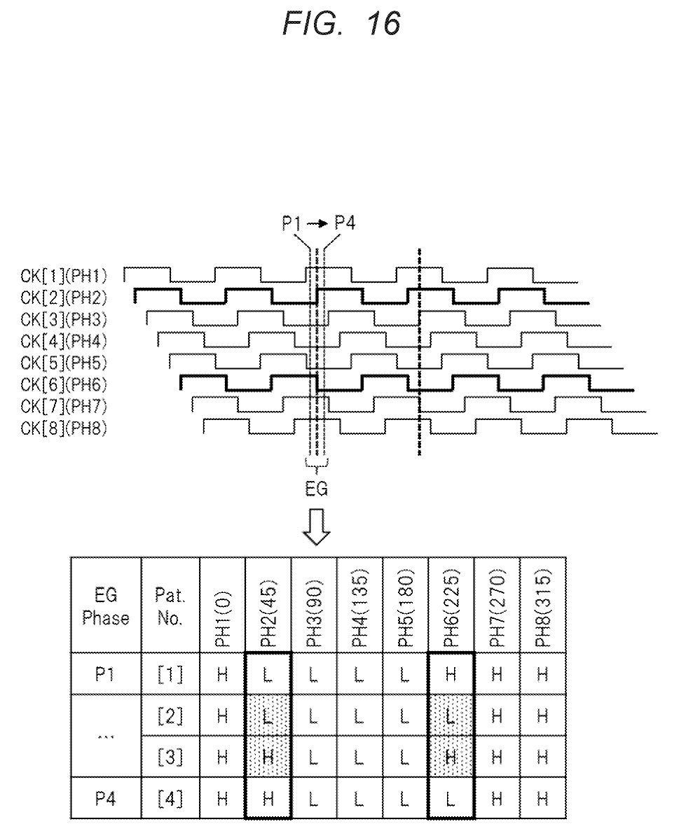

FIG. 16 is a schematic diagram illustrating a third problem in the clock data recovery circuit using the digital circuit method. For example, in the flip-flops FF within the phase detector PHDx as shown in FIG. 13, metastability may occur. Metastability refers to a state where the latch data becomes indeterminate state due to not meeting the setup time or hold time of the flip-flop FF.

Here, as shown in FIG. 16, it is assumed that the phase of the edge EG of the data signal DAT gradually lags from phase P1 to phase P4 due to periodic jitter. The 8-bit phase detection data from the phase detector PHDx indicates pattern [1], “HLLLLHHH”, at phase P1, and pattern [4], “HHLLLLHH”, at phase P4. On the other hand, the 8-bit phase detection data may indicate pattern [2], “HLLLLLHH”, or pattern [3], “HHLLLHHH”, due to metastability at phases between phase P1 and phase P4. That is, a state of mismatch between the number of “H” levels and the number of “L” levels may occur.

The clock data recovery circuit sequentially selects phases PH5, PH6, PH5, PH6 according to patterns [1], [2], [3], [4]. In this case, while the phase of the edge EG of the data signal DAT is advancing in one direction, the phase PH of the selected clock signal CK advances in two directions. As a result, similar to the case in FIG. 15, the phase error dPH may temporarily increase, which can degrade the communication performance between chips.

### Outline of the Timing Adjustment Circuit

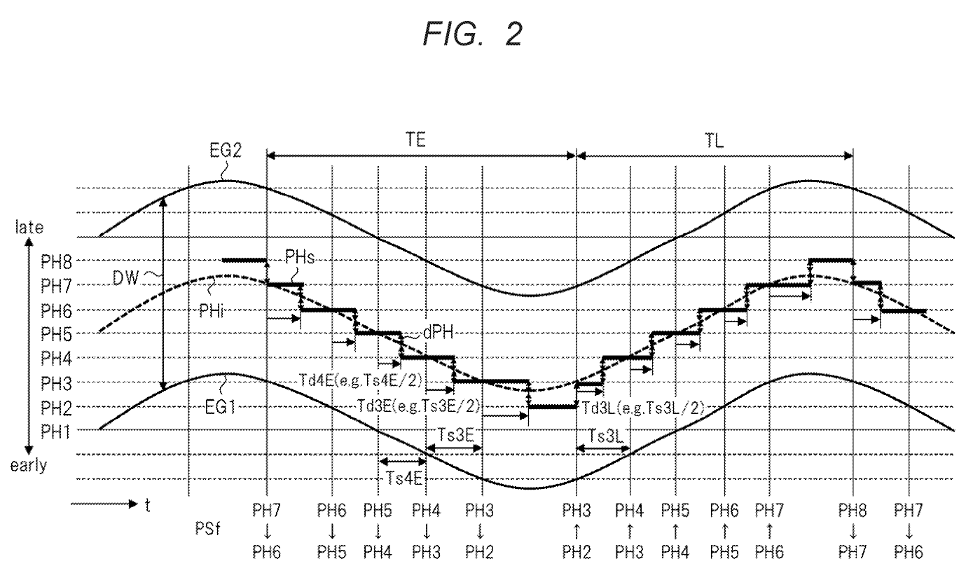

To solve the aforementioned first problem, a timing adjustment circuit TADJ is provided in FIG. 1. FIG. 2 is a schematic diagram showing an example of the operation of the timing adjustment circuit TADJ in FIG. 1. FIG. 2 shows, similar to the case in FIG. 14, time variations of two adjacent edges EG1 and EG2 in the data signal DAT. Also shown is the time variation between the ideal phase PHi of the clock signal CK and the actually selected phase PHs. The timing adjustment circuit TADJ receives the N-bit phase selection signal PSf from the phase judgement circuit PJDG. Based on the N-bit phase selection signal PSf, change of phase PHs is instructed, as similar to the case of FIG. 14.

The timing adjustment circuit TADJ receives the N-bit phase selection signal PSf and adds a delay time determined for each selected phase PHs to it. In this way, the timing adjustment circuit TADJ outputs the N-bit delayed phase selection signal PSd at a timing corresponding to the selected phase PHs.

Specifically, the timing adjustment circuit TADJ first measures the length of the selection time Ts for each phase PHs specified by the phase selection signal PSf. As a specific example, during an early transition period TE in which the phase PH to be selected switches in an earlier phase direction, the length of the selection time Ts4E for phase PH4 and the length of the selection time Ts3E for phase PH3 are measured. Furthermore, during the late transition period TL when the phase PH to be selected switches in a later phase direction, the length of the selection time Ts3L for phase PH3 is measured.

In this way, the timing adjustment circuit TADJ individually measures the length of the selection time Ts for each phase PH during the early transition period TE (first period) and the late transition period TL (second period) and individually retains the measurement results. The lengths of the selection time Ts4E and the selection time Ts3E may be different from each other. The lengths of the selection time Ts3E and the selection time Ts3L may be different from each other. The timing adjustment circuit TADJ determines the delay time for outputting the delayed phase selection signal PSd during the subsequent period based on the measured selection time.

As a specific example, the timing adjustment circuit TADJ outputs the delayed phase selection signal PSd indicating the selection of phase PH4, after the delay time Td4E has elapsed since phase PH4 was selected based on the phase selection signal PSf. Similarly, the timing adjustment circuit TADJ outputs the delayed phase selection signal PSd indicating the selection of phase PH3 after the delay time Td3E has elapsed since phase PH3 was selected based on the phase selection signal PSf. In this disclosure, each delay time Td4E, Td3E, ... is collectively referred to as delay time Td.

Here, it is desirable for the timing adjustment circuit TADJ to set the delay time Td for outputting the delayed phase selection signal PSd to half the length of the measured selection time Ts. That is, the two delay times Td4E and Td3E should be half the length of the measured selection times Ts4E and Ts3E, respectively.

Additionally, as shown in FIG. 2, the method of selecting the phase PHs differs slightly between the early transition period TE and the late transition period TL. For example, consider the case where, during the early transition period TE, the selected phase PHs indicated by the phase selection signal PSf switches from phase PH4 (the third phase) to phase PH3 (the second phase). In this case, the timing adjustment circuit TADJ waits for the delay time Td3E (first delay time) for phase PH3 after switching from phase PH4 to phase PH3. Then, the timing adjustment circuit TADJ outputs the delayed phase selection signal PSd, which indicates the selection of the phase PH3 (the second phase), after the delay time Td3E has elapsed.

On the other hand, for example, consider the case where, during the late transition period TL, the selected phase PHs indicated by the phase selection signal PSf switches from phase PH2 (the first phase) to phase PH3 (the second phase). In this case, the timing adjustment circuit TADJ waits for the delay time Td3L (second delay time) for phase PH3 after switching from phase PH2 to phase PH3. Then, after the delay time Td3L has elapsed, the timing adjustment circuit TADJ outputs the delayed phase selection signal PSd indicating the next phase PH4 (the third phase) instead of phase PH3 (the second phase).

In reference to such differences, the phase judgement circuit PJDG, as above-mentioned, selects phase PH3 based on the phase selection signal PSf when the ideal phase PHi exists between phase PH3 and phase PH4, for example. That is, phase PH3 is selected based on reaching phase PH4 during the early transition period TE and based on reaching phase PH3 during the late transition period TL. Due to such differences, using the same selection method for both of the early transition period TE and the late transition period TL results in a selection shift of one phase. In this example, the timing adjustment circuit TADJ uses a slightly different phase selection method for every two transition periods.

By providing such a timing adjustment circuit TADJ, the phase error dPH, in other words, the quantization error, can be reduced by using slightly different phase selection methods for each of the two transition periods, the early transition period TE and the late transition period TL. That is, the phase PHs to be selected can be brought closer to the ideal phase PHi. In particular, by setting the delay time Td to half the length of the measured selection time Ts, the magnitude of the phase error dPH can be reduced to half of that in the case of FIG. 14. As a result, the communication performance between chips can be improved. Specifically, high-speed in communication can be achieved. Alternatively, the BER can be reduced.

### Details of the Timing Adjustment Circuit

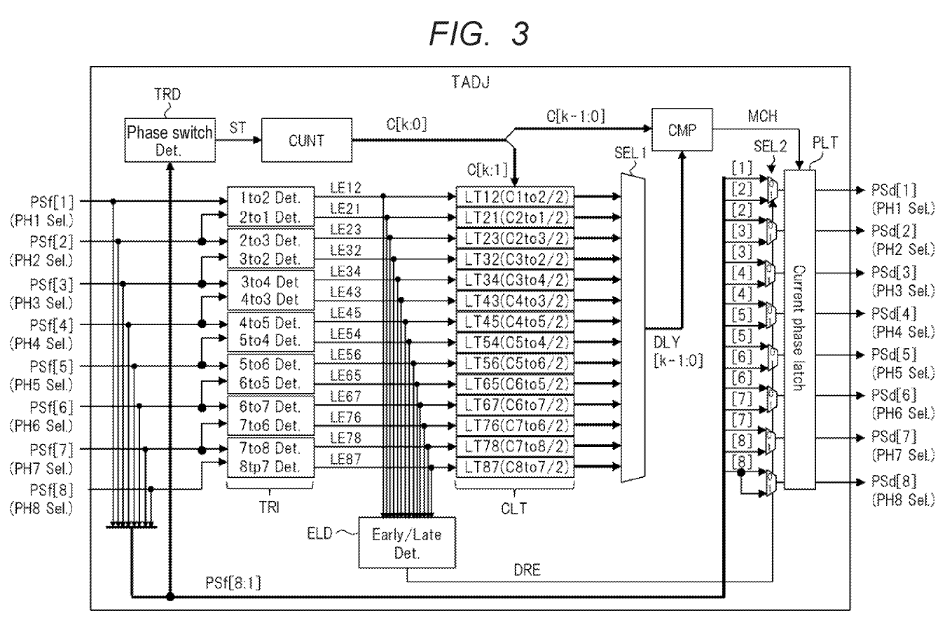

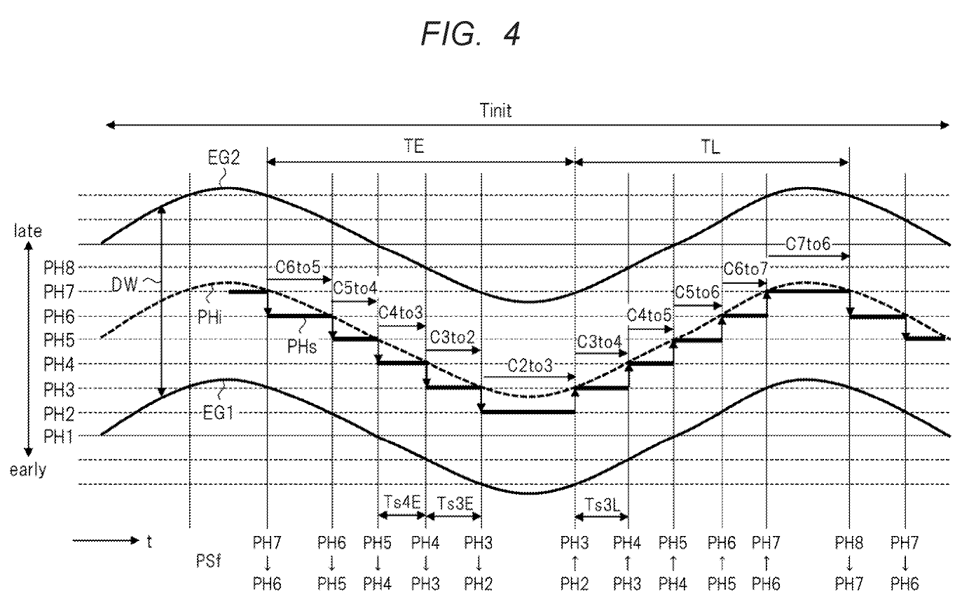

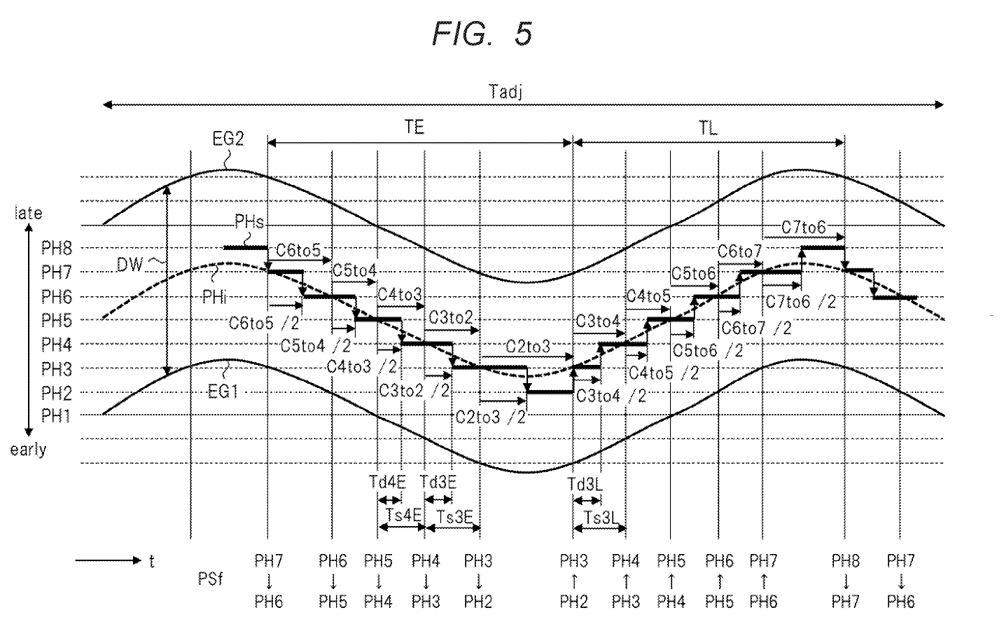

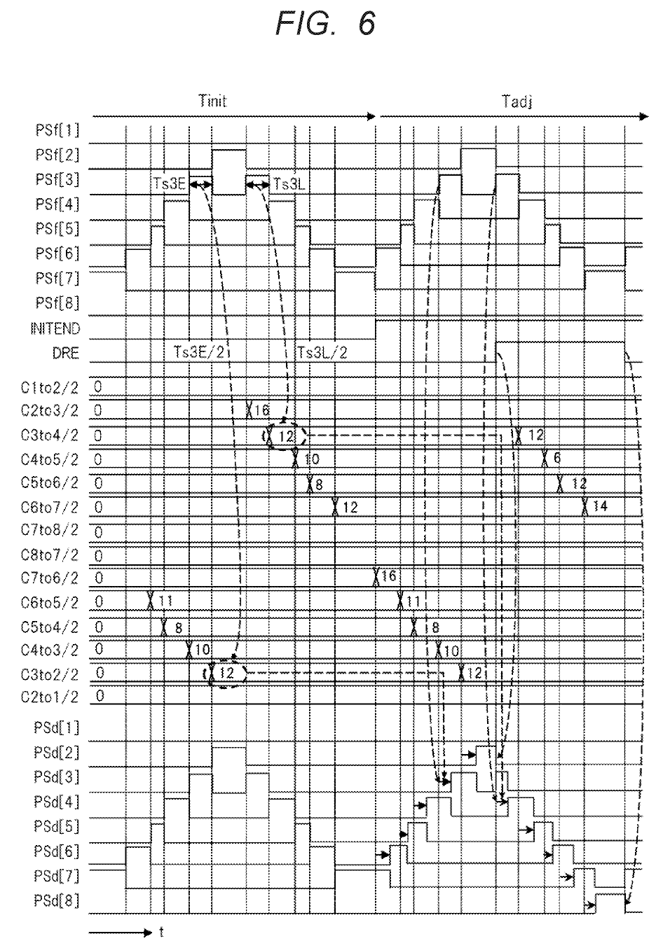

FIG. 3 is a circuit block diagram showing a configuration example of the main part of the timing adjustment circuit TADJ in FIG. 1. FIGS. 4 and 5 are supplementary diagrams for explaining an example of the operation of the timing adjustment circuit TADJ shown in FIG. 3. FIG. 6 is a timing chart showing an example of the operation of the timing adjustment circuit TADJ shown in FIG. 3.

First, as shown in FIGS. 4 and 5, the operation period of the timing adjustment circuit TADJ includes an initial period Tinit and an adjustment period Tadj after the initial period Tinit. The initial period Tinit is, for example, a training period generally provided in the clock data recovery circuit CDR. The adjustment period Tadj is the period during which the timing adjustment operation as described in FIG. 2 is actually executed.

During the initial period Tinit, as shown in FIG. 4, the timing adjustment circuit TADJ selects phase PHs at the same timing as in the case of FIG. 14. Namely, the timing adjustment circuit TADJ outputs the phase selection signal PSf from the phase judgement circuit PJDG directly to the clock selection circuit CKMUX. The timing adjustment circuit TADJ measures the initial value of the selection time Ts described in FIGS. 2 and 14 as a count value during the initial period Tinit.

As a specific example, the timing adjustment circuit TADJ measures the initial value of the selection time Ts4E for phase PH4 during the early transition period TE as the count value C4to3. Similarly, the timing adjustment circuit TADJ measures the initial value of the selection time Ts3E for phase PH3 during the early transition period TE as the count value C3to2. In addition, the timing adjustment circuit TADJ measures the initial value of the selection time Ts3L for phase PH3 during the late transition period TL as the count value C3to4.

Subsequently, during the adjustment period Tadj, as shown in FIG. 5, the timing adjustment circuit TADJ selects the phase PHs at the same timing as in the case of FIG. 2. As a specific example, the timing adjustment circuit TADJ sets the delay time Td4E for selecting phase PH4 during the early transition period TE to half the count value C3to4. Similarly, the timing adjustment circuit TADJ sets the delay time Td3E for selecting phase PH3 during the early transition period TE to half the count value C3to2.

Additionally, the timing adjustment circuit TADJ sets the delay time Td3L for selecting phase PH4 in the late transition period TL to half the count value C3to4. Here, the timing adjustment circuit TADJ may use the value obtained by excluding the least significant bit from the measured count value C3to4 when determining the count value for the delay time Td3L. That is, the value obtained by right-shifting the measured count value C3to4 by one bit may be used.

FIG. 6 shows a timing chart for the initial period Tinit and the adjustment period Tadj. Here, the 8-bit phase selection signals PSf[1]-PSf[8] from the phase judgment circuit PJDG, the initial period end signal INITEND, and the transition direction identification signal DRE are shown. Also, the count values for the delay time described in FIG. 5, such as “C3to4/2", “C3to2/2", etc., are shown. Furthermore, the 8-bit delayed phase selection signals PSd[1]-PSd[8] from the timing adjustment circuit TADJ are shown.

The 8-bit phase selection signals PSf[1]-PSf[8] are signals corresponding to the 8 phases PH1-PH8, and are asserted to the “H” level when selecting a phase PH. This is also the case for the 8-bit delayed phase selection signals PSd[1]-PSd[8]. The initial period end signal INITEND is a signal that is asserted when the predetermined initial period Tinit ends. The timing adjustment circuit TADJ distinguishes and executes the operations shown in FIGS. 4 and 5 based on the initial period end signal INITEND.

The transition direction identification signal DRE is a signal that distinguishes between the early transition period TE and late transition period TL. The timing adjustment circuit TADJ can generate the transition direction identification signal DRE based on the temporal changes of the phase selection signals PSf[1]-PSf[8]. In this example, the timing adjustment circuit TADJ detects the transition to the late transition period TL when the phase selection signal PSf[3] is asserted after the phase selection signal PSf[2] is asserted. Additionally, the timing adjustment circuit TADJ detects the transition to the early transition period TE when the phase selection signal PSf[6] is asserted after the phase selection signal PSf[7] is asserted.

During the initial period Tinit, the timing adjustment circuit TADJ counts the assertion time of the phase selection signal PSf[3] during the early transition period TE as the selection time Ts3E. Then, the timing adjustment circuit TADJ latches the count value “C3to2/2", which is half of the count value. Similarly, the timing adjustment circuit TADJ counts the assertion time of the phase selection signal PSf[3] during the late transition period TL as the selection time Ts3L. Then, the timing adjustment circuit TADJ latches the count value “C3to4/2”, which is half of the count value.

Subsequently, during the adjustment period Tadj, the timing adjustment circuit TADJ detects the assertion of the phase selection signal PSf[3] in the early transition period TE. The timing adjustment circuit TADJ starts counting up from the time the assertion is detected. Then, the timing adjustment circuit TADJ asserts the delayed phase selection signal PSd[3] when the count value matches the latched count value “C3to2/2”. At the same time, the timing adjustment circuit TADJ negates the delayed phase selection signal PSd[4].

Additionally, during the adjustment period Tadj, the timing adjustment circuit TADJ detects the assertion of the phase selection signal PSf[3] in the late transition period TL. The timing adjustment circuit TADJ starts counting up from the time the assertion is detected. Then, the timing adjustment circuit TADJ asserts the delayed phase selection signal PSd[4] when the count value matches the latched count value “C3to4/2”. At the same time, the timing adjustment circuit TADJ negates the delayed phase selection signal PSd[3].

Note that the timing adjustment circuit TADJ asserts/negates the delayed phase selection signal PSd immediately without going through the aforementioned delay time Td when the transition direction identification signal DRE switches. As above-mentioned, slightly different phase selection methods are used for the early transition period TE and the late transition period TL. To absorb the difference in selection methods, the delayed phase selection signal PSd is also switched immediately when the transition direction identification signal DRE switches.

Additionally, the timing adjustment circuit TADJ sequentially updates the count value of the selection time Ts during the adjustment period Tadj. As a result, the timing adjustment circuit TADJ determines the delay time Td based on the latest count value of the selection time Ts. That is, the timing adjustment circuit TADJ outputs the delayed phase selection signal PSd after the delay time Td based on the measurement result of the selection time Ts. In parallel, the timing adjustment circuit TADJ measures the length of the latest selection time Ts to determine the delay time Td for the next occurrence of the same phase switch. This allows for phase selection based on the most recent phase changes at all times.

Based on the above operations, the timing adjustment circuit TADJ shown in FIG. 3 includes a phase switch detection circuit TRD, a counter CUNT, a switch target identification circuit TRI, and a count value latch circuit CLT. The timing adjustment circuit TADJ also includes a selector SEL1 and a comparator CMP. Furthermore, the timing adjustment circuit TADJ includes a transition direction detection circuit ELD, a selector SEL2, and a phase latch circuit PLT.

The phase switch detection circuit TRD detects that a phase switch has occurred based on the 8-bit phase selection signals PSf[1]-PSf[8]. The phase switch detection circuit TRD outputs a start signal ST to the counter CUNT each time a phase switch occurs. The counter CUNT starts counting up from zero each time it receives a start signal ST. That is, the counter CUNT starts counting up from zero each time the phase PHs selected by the phase selection signal PSf switches.

The switch target identification circuit TRI identifies, based on the 8-bit phase selection signals PSf[1]-PSf[8], the phases PH before and after switching. Then, the switch target identification circuit TRI outputs a latch enable signal corresponding to the combination of the two identified phases PH when switching the phase PHs selected by the phase selection signal PSf. When using 8 phases PH, the switch target identification circuit TRIs outputs 14 latch enable signals LE(12,23,...,78,87,76,...,21) in total.

The count value latch circuit CLT includes 14 latch circuits LT (12,23,...,78,87,76,...,21) for latching 14 count values. Each of the 14 latch circuits LT latches the count value of the delay time Td based on the count value C[k:0] of the counter CUNT according to the 14 latch enable signals LE. At this time, the count value latch circuit CLT latches the count value C[k:1] as the delay time Td, excluding the least significant 1 bit in the counter CUNT, as described in FIG. 5.

The selector SEL1 outputs one of the 14 count values C[k:1] held by the count value latch circuit CLT as the delay value DLY[k-1:0] based on the 8-bit phase selection signals PSf[1]-PSf[8]. The comparator CMP receives the delay value DLY[k-1:0] and the count value C[k-1:0] excluding the most significant bit in the counter CUNT. Then, the comparator CMP compares the two received count values and outputs a match signal MCH when they match.

The transition direction detection circuit ELD generates the transition direction identification signal DRE as described in FIG. 6 based on the 14 latch enable signals LE from the switch target identification circuit TRI. The selector SEL2 selects the destination phase PH according to the transition direction identification signal DRE. For example, as shown in FIGS. 2 or 6, in the late transition period TL, the destination phase PH becomes the late phase PH.

The phase latch circuit PLT includes, for example, SR latch circuits. The phase latch circuit PLT asserts the delayed phase selection signal PSd corresponding to the phase PH to be selected from the selector SEL2 according to the match signal MCH from the comparator CMP. At the same time, the phase latch circuit PLT negates the delayed phase selection signal PSd corresponding to the phase PH that has been selected.

### Details of the Phase Detector

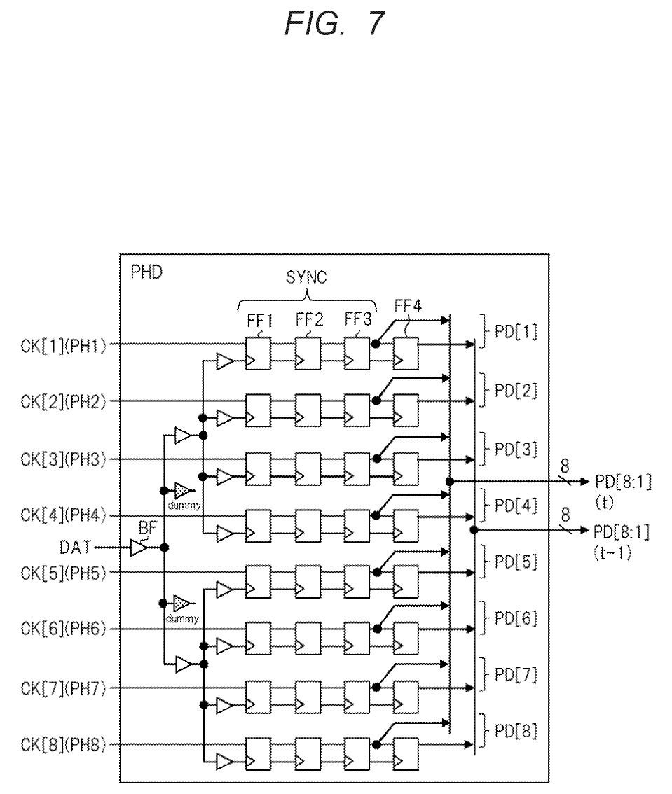

FIG. 7 is a circuit diagram showing a detailed configuration example of the phase detector PHD in FIG. 1. The phase detector PHD, together with the phase judgment circuit PJDG described later, has a configuration to solve the second problem described in FIG. 15. The phase detector PHD shown in FIG. 7 corresponds to each of the two phase detectors PHDp and PHDn shown in FIG. 1. The phase detector PHD includes a four-stage flip-flip FF1-FF4 that has four flip-flops FF1-FF4 coupled in series for each of the N-phase, here 8-phase, clock signals CK[1]-CK[8]. The four-stage flip-flop FF1-FF4 latch the corresponding clock signal CK at the rising edge of the data signal DAT.

Specifically, as described in FIG. 1, each flip-flop FF1-FF4 (first flip-flop) in the phase detector PHDp latches the clock signal CK at the rising edge of the data signal DAT. On the other hand, each flip-flop FF1-FF4 (second flip-flop) in the phase detector PHDn equivalently latches the clock signal CK at the falling edge of the data signal DAT.

In the path of the data signal DAT, buffers BF are appropriately inserted to reduce timing variations due to wiring load, similar to a typical clock tree. The buffer BF may include dummy buffers. Here, the first to third stages of the four-stage flip-flop FF1-FF4, FF1-FF3, serve as a synchronization circuit SYNC to converge metastability. In FIG. 7, a final stage flip-flop FF4 is added to this synchronization circuit SYNC.

Thus, the phase detector PHD outputs 8-bit phase detection data PD[8:1](t) as the latest data from the synchronization circuit SYNC, specifically from the third-stage flip-flop FF3. Additionally, the phase detector PHD outputs the previous data, 8-bit phase detection data PD[8:1](t-1), from the final stage flip-flop FF4. With such a configuration, the phase detector PHDp outputs two consecutive phase detection data PDp(t), PDp(t-1) at the rising edge of the data signal DAT. Similarly, the phase detector PHDn outputs two consecutive phase detection data PDn(t), PDn(t-1) at the falling edge of the data signal DAT.

Then, the two phase detectors PHDp and PHDn output the four consecutive past phase detection data PDp(t), PDn(t), PDp(t-1), PDn(t-1). For example, in response to a rising edge of the data signal DAT, the associated phase detection data PD(t) is output. At this time, the remaining three phase detection data PDn(t), PDp(t-1), PDn(t-1) indicate the data associated with the previous falling edge, the second previous rising edge, and the third previous falling edge, respectively.

Note that, with M being an integer of 3 or more, the phase detector PHD should output consecutive M phase detection data PD. FIG. 7 shows a configuration example for the case of M=4 or M=3. In this case, as shown in FIG. 7, one stage of flip-flop FF4 should be added to the synchronization circuit SYNC. In the case of M=3, the set of three phase detection data PDp(t), PDn(t), PDp(t-1) and the set of three phase detection data PDn(t), PDp(t), PDn(t-1) should be alternately selected. Similarly, in the case of M=6 or M=5, two stages of flip-flops should be added to the synchronization circuit SYNC.

### Details of the Phase Judgement Circuit

The phase judgement circuit PJDG shown in FIG. 1 selects one phase of the N phases based on consecutive M phase detection data PDp, PDn from the phase detector PHD. More specifically, the phase judgement circuit PJDG includes a metastability removal circuit MSR and a majority decision circuit MDC.

The metastable removal circuit MSR receives the M phase detection data PDp, PDn from the phase detector PHD. Then, the metastable removal circuit MSR outputs M phase selection signals (intermediate phase selection signals) PSp, PSn by selecting the phase PH for each of the M phase detection data PDp and PDn. Details will be described later, but the metastable removal circuit (MSR) appropriately removes the influence when metastability is included in the phase detection data PDp, PDn during phase selection.

In the example shown in FIG. 1, the metastable removal circuit (MSR) receives consecutive four phase detection data, PDp(t), PDn(t), PDp(t-1) and PDn(t-1). Then, the metastable removal circuit MSR performs phase selection for each set of four data and outputs four phase selection signals, PSp(t), PSn(t), PSp(t-1), and PSn(t-1). The phase selection signals PSp, PSn are N-bit signals that indicate the phase to be selected in one hot, similar to the phase selection signal PSf shown in FIG. 6.

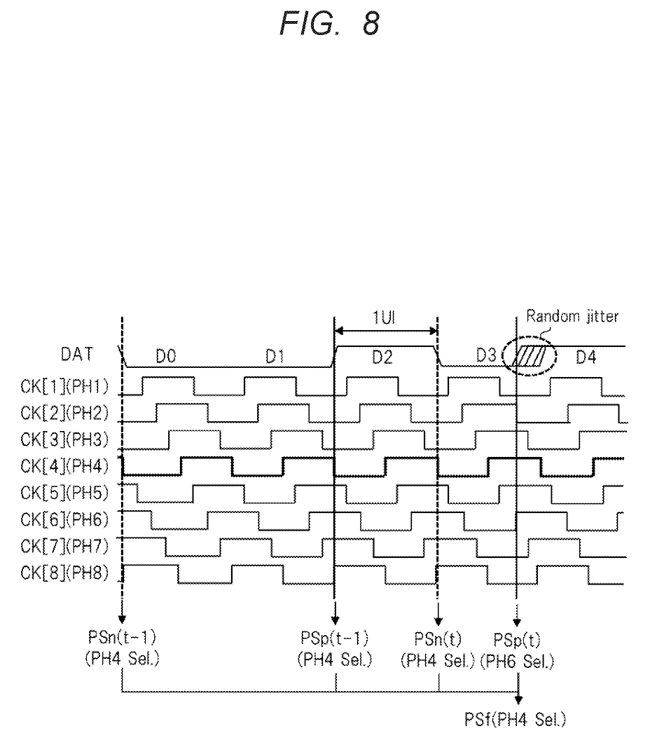

FIG. 8 is a timing chart showing an example of the operation of the majority decision circuit MDC in FIG. 1. The majority decision circuit MDC receives consecutive M phase selection signals (intermediate phase selection signals) PSp, PSn from the metastable removal circuit MSR. The majority decision circuit MDC performs a majority decision on the received M phase selection signals PSp, PSn, that is, the M phase detection data PDp, PDn from the phase detector PHD. The majority decision circuit MDC selects one phase from among the N phases based on the majority decision result and outputs the final phase selection signal PSf indicating the phase to be selected.

In the examples shown in FIGS. 8 and 1, the majority decision circuit MDC receives the consecutive 4 phase selection signals Psp(t), PSn(t), PSp(t-1) and PSn(t-1) from the metastable removal circuit MSR. Among these, three phase selection signals PSn(t), PSp(t-1), PSn(t-1) indicates the selection of phase PH4. The remaining one phase selection signal PSn(t) indicates the selection of phase PH6 due to random jitter as shown in FIG. 15. In this case, the majority decision circuit MDC selects phase PH4 based on the majority decision result and outputs the phase selection signal PSf indicating phase PH4.

Note that while M=4 is shown here as an example, as shown in FIG. 7, M may be any integer of 3 or more. For example, in the case of M=3, at the rising edge of the data signal DAT, a majority decision should be made on the phase selection signals for consecutive three PSp(t), PSn(t), PSp(t-1). Also, at the falling edge of the data signal DAT, a majority decision should be made on the phase selection signals for consecutive three PSn(t), PSp(t), PSn(t-1).

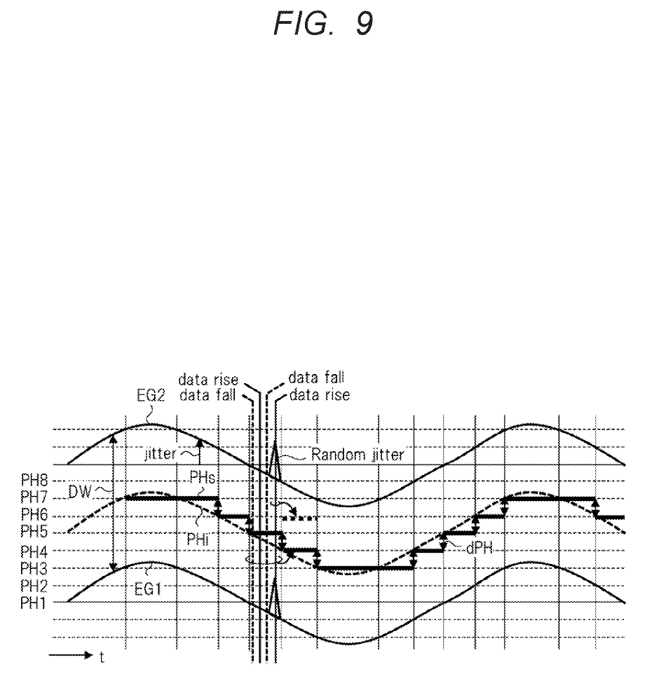

FIG. 9 is a schematic diagram showing an example of the operation of the majority decision circuit MDC in FIG. 1. FIG. 9 shows the time variation of two edges EG1, EG2 in the data signal DAT, similar to the case in FIG. 15. The random jitters in addition to periodic jitters occur on the two edges EG1, EG2, similar to the case in FIG. 15. In the case of FIG. 15, phase PH6 is selected according to the latest rising edge of the data signal DAT. In contrast, in the case of FIG. 9, the phase PH4 can be selected according to the latest rising edge of the data signal DAT.

This allows for the suppression of the temporary increase in phase error dPH, unlike in the case of FIG. 15. As a result, communication performance between chips is improved. Specifically, in the data latch circuit DLT, errors are less likely to occur when obtaining the data signal DATr, i.e., the recovered data signal, by using the selected phase PH4. As a result, the BER is reduced.

Note that if M is an even number, for example, M=4, the majority decision result can be equal, i.e., 2 to 2. For example, in the absence of random jitter, four phase selection results at a certain point in time may be obtained as phase PH3, phase PH3, phase PH4, phase PH4, in order from the latest result. In this case, the majority decision circuit MDC may select one of the two based on a predetermined rule, such as prioritizing the latest result.

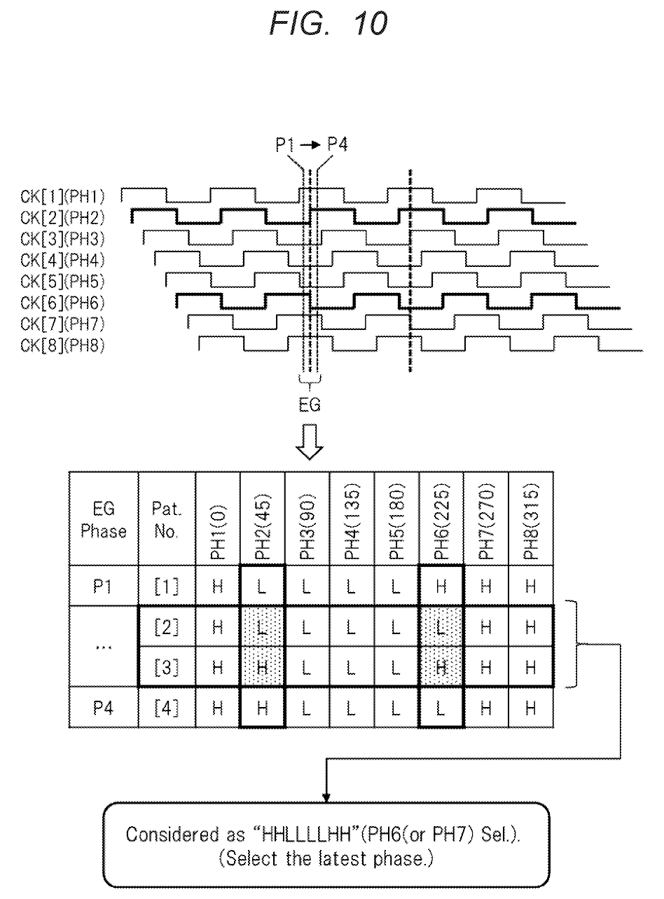

FIG. 10 is a schematic diagram showing an example of the operation of the metastable removal circuit MSR in FIG. 1. FIG. 10 shows the situation where the phase of the edge EG of the data signal DAT gradually lags from phase P1 to phase P4 due to periodic jitter, similar to the case in FIG. 16. And, between phase P1 and phase P4, patterns [2], “HLLLLLHH”, and pattern [3], “HHLLLHHH”, are generated due to metastable. That is, a state of mismatch between the number of “H” levels and “L” levels occurs.

In this case, the metastable removal circuit MSR considers pattern [2] and pattern [3] as “HHLLLLHH”. That is, as shown in FIG. 13, normally, if such pattern [2] and pattern [3] occur, phases PH6 and PH5 are selected, respectively. On the other hand, when the number of “H” levels and the number of “L” levels are inconsistent, i.e., when metastable state occurs, the metastable removal circuit MSR considers the correct phase candidates, here phase PH6 and phase PH5. Then, the metastable removal circuit MSR selects the slowest phase PH6 from among phase PH6 and phase PH5 that are the multiple correct phase candidates. Note that, similar to the case in FIG. 13, the selected phase may also be phase PH7.

Here, the phase detector PHD shown in FIG. 1 and FIG. 7 latches the clock signal CK at the edge of the data signal DAT. Therefore, the phase PH of the clock signal CK is adjusted in the early direction by the setup time of the flip-flop FF. Therefore, the metastable removal circuit MSR suppresses the shift to the early side by selecting the late side phase PH from multiple candidates when metastability occurs. From this perspective, the metastable removal circuit MSR may select phase PH7 in the case of FIG. 10.

By providing such a metastable removal circuit MSR, it is possible to prevent situations where the phase error dPH temporarily increases due to metastability, as described in FIG. 16. As a result, the communication performance between chips can be improved. Specifically, in the data latch circuit DLT, it becomes less likely for errors to occur when obtaining the data signal DATr, i.e., the recovered data signal, using the selected phase PH. Furthermore, by selecting the late side phase PH, it becomes even less likely for errors to occur. As a result, the BER can be reduced. Alternatively, high-speed communication can be achieved.

Depending on occurrence of metastability, the number of “H” levels and “L” levels may match. In this case, the metastable removal circuit MSR cannot recognize the occurrence of metastability. As a specific example of a problem associated with this, where it should progress from pattern [1] to pattern [4], it may progress from pattern [4] to pattern [1] due to metastability.

Such problems cannot be solved by the metastable removal circuit MSR. However, it can be resolved by using the aforementioned majority decision circuit MDC. That is, it can be resolved by using M phase detection data PD including phase detection data PD where metastability has not occurred. Therefore, it is desirable for the metastable removal circuit MSR to be used in conjunction with the majority decision circuit MDC.

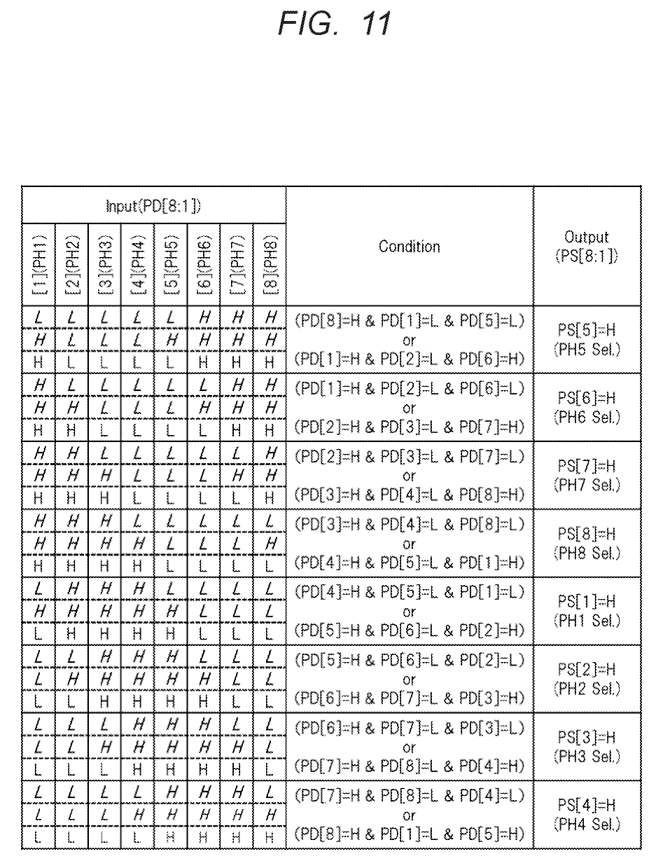

FIG. 11 is a table showing an example of the input-output operation of the metastable removal circuit MSR in FIG. 1. FIG. 11 shows the input-output table in the metastable removal circuit MSR. The input-output table shows the correspondence between the phase detection data PD, which is the input to the metastable removal circuit MSR, and the phase selection signal (intermediate phase selection signal) PS, which is the output from the metastable removal circuit MSR. Additionally, the input-output table is predetermined considering the phase detection data PD that includes metastability. The metastable removal circuit MSR operates based on such an input-output table.

In the input-output table shown in FIG. 11, the metastable removal circuit MSR selects phase PH6 when, for example, pattern [4], “HHLLLLHH”, shown in FIG. 10 is input. In addition, the metastable removal circuit MSR also selects phase PH6 when the pattern [2], “HLLLLLHH”, or pattern [3], “HHLLLHHH”, shown in FIG. 10 is input. At this time, the metastable removal circuit MSR may select phase PH7 instead of phase PH6.

In this phase selection, the metastable removal circuit MSR may select phase PH6 when, for example, phase detection data PD[1], PD[2], and PD[6] are “H”, “L”, and “L”, respectively. Alternatively, the metastable removal circuit MSR may select phase PH6 when phase detection data PD[2], PD[3], and PD[7] are “H”, “L”, and “H”, respectively.

Similarly, the metastable removal circuit MSR selects phase PH7 when, for example, “HHHLLLLH” is input as phase detection data PD. In addition, the metastable removal circuit MSR also selects phase PH7 when “HHLLLLLH” or “HHHLLLHH” including metastability is input. At this time, the metastable removal circuit MSR may select phase PH8 instead of phase PH7.

In this phase selection, the metastable removal circuit MSR may select phase PH7 when, for example, phase detection data PD[2], PD[3], and PD[7] are “H”, “L”, and “L”, respectively. Alternatively, the metastable removal circuit MSR may select phase PH7 when phase detection data PD[3], PD[4], and PD[8] are “H”, “L”, and “H”, respectively.

The phase detection data PD becomes data where “H” or “L” is continuous in adjacent bits. Therefore, the determination conditions can be simplified in this way. That is, the metastable removal circuit MSR can select phase PH based on the value of 3 bits out of 8 bits. The input-output table shown in FIG. 11 can be implemented as a logic circuit, for example. At this time, by simplifying the determination conditions, the logic circuit can also be simplified.

### Main Effects According to the Embodiment

As described above, in the clock data recovery circuit CDR according to the embodiment, a digital method where the clock signal CK is latched at the edge of the data signal DAT is used. As a result, compared to using an analog method, it is possible to reduce the cost and shorten the TAT of the semiconductor device. In addition, in the embodiment, a timing adjustment circuit TADJ is provided to output a delayed phase selection signal PSd at the timing corresponding to the selected phase. This improves the communication performance between chips, i.e., between semiconductor devices, such as reducing BER and accelerating communication.

Furthermore, in the embodiment, the metastable removal circuit MSR to remove the influence of metastability, or the majority decision circuit MDC to determine the selected phase PH by majority vote, is provided. This further improves the communication performance between semiconductor devices. By improving communication performance while achieving cost reduction and TAT shortening of semiconductor devices, particularly beneficial effects can be obtained when applied to Chiplet.

### Additional Statement

### (Additional Statement A1)

A semiconductor device comprising:

a phase detector that receives a data signal andN-phase clock signals having phases different from each other, where N is an integer of 2 or more, and outputs N-bit phase detection data by latching the N-phase clock signals at the edge of the data signal;

a phase judgement circuit that selects one of the N phases based on the N-bit phase detection data and outputs a phase selection signal representing the phase to be selected; and

a clock selection circuit that receives the N-phase clock signals and selects and outputs one of the N-phase clock signals according to the phase selection signal; and

a data latch circuit that latches the data signal with the clock signal selected by from the clock selection circuit,

wherein the phase judgement circuit selects one of the N phases based on M consecutive phase detection data from the phase detector, where M is an integer of 3 or more.

### (Additional Statement A2)

The semiconductor device according to Additional Statement A1, wherein the phase judgement circuit includes a majority decision circuit that selects one of the N phases by performing a majority decision on the M consecutive of phase detection data.

### (Additional Statement A3)

The semiconductor device according to Additional Statement A1, wherein the phase detector includes a first flip-flop that outputs first phase detection data by latching the N phase clock signals at the rising edge of the data signal, and a second flip-flop that outputs second phase detection data by latching the N phase clock signals at the falling edge of the data signal. The M instances of phase detection data include the first phase detection data and the second phase detection data.

### (Additional Statement A4)

The semiconductor device according to Additional Statement A2,

wherein N is an even number,

wherein the phase judgement circuit further includes a metastable removal circuit that inputs the M phase detection data from the phase detector, selects one of the N phases for each of the M phase detection data, and outputs M intermediate phase selection signals representing the selected phase,

wherein the majority decision circuit outputs the phase selection signal by performing a majority decision on the M intermediate phase selection signals from the metastable removal circuit, and

wherein the metastable removal circuit selects the slowest phase from multiple phase candidates when the number of “H” levels and “L” levels included in the N-bit phase detection data are inconsistent due to metastability.

### (Additional Statement A5)

The semiconductor device according to Additional Statement A4,

wherein the metastable removal circuit operates based on an input-output table, the input-output table represents the correspondence between the N-bit phase detection data and the intermediate phase selection signal and is predetermined by considering the N-bit phase detection data including metastability.

### (Additional Statement B1)

A semiconductor device comprising:

a phase detector that receives a data signal and N-phase clock signals having phases different from each other, where N is an even number, and outputs N-bit phase detection data by latching the N-phase clock signals at the edge of the data signal;

a phase judgement circuit that selects one of the N phases based on the N-bit phase detection data and outputs a phase selection signal representing the phase to be selected;

a clock selection circuit that inputs the N-phase clock signals and selects and outputs one of the N-phase clock signals according to the phase selection signal; and

a data latch circuit that latches the data signal with the clock signal selected by the clock selection circuit,

wherein the phase judgement circuit includes a metastable removal circuit that selects the slowest phase from multiple phase candidates when the number of “H” levels and “L” levels included in the N-bit phase detection data are inconsistent due to metastability.

### (Additional Statement B2)

The semiconductor device according to Additional Statement B1,

wherein the metastable removal circuit operates based on an input-output table, the input-output table represents the correspondence between the N-bit phase detection data and the phase selection signal and is predetermined by considering the N-bit phase detection data including the metastable.

Although the invention made by the inventor has been specifically described based on the embodiment, the present invention is not limited to the embodiment described, and various modifications can be made without departing from the gist thereof. For example, the aforementioned embodiment has been described in detail to clearly explain the present invention and is not necessarily limited to including all the configurations described. Furthermore, it is possible to replace part of the configuration of one embodiment with the configuration of another embodiment, and it is also possible to add the configuration of another embodiment to the configuration of one embodiment. Additionally, it is possible to add, delete, or replace parts of the configuration of each embodiment with other configurations.

What is claimed is:

1. A semiconductor device comprising:
a phase detector configured to receive a data signal and N-phase clock signals having phases different from each other, where N is an integer of 2 or more, and output N-bit phase detection data by latching the N-phase clock signals at the edge of the data signal;
a phase judgement circuit configured to select one of the N phases based on the N-bit phase detection data and output a phase selection signal indicating the phase to be selected;
a timing adjustment circuit configured to receive the phase selection signal, and output a delayed phase selection signal by delaying the phase selection signal by a delay time determined for each phase to be selected;
a clock selection circuit configured to receive the N-phase clock signals and select and output a clock signal having a phase selected by the delayed phase selection signal out of the N-phase clock signals, and
a data latch circuit that latches the data signal with the clock signal that has been selected by the clock selection circuit.

2. The semiconductor device according to claim 1, wherein the timing adjustment circuit is configured to measure the length of the selection time for each phase specified by the phase selection signal and determine the delay time for outputting the delayed phase selection signal in the subsequent period based on the selection time that has been measured.

3. The semiconductor device according to claim 2, wherein the timing adjustment circuit is configured to determine the delay time for outputting the delayed phase selection signal to be half the length of the selection time that has been measured.

4. The semiconductor device according to claim 3, wherein the timing adjustment circuit includes a counter and a count value latch circuit,
wherein the counter starts counting up from zero each time the phase to be selected based on the phase selection signal is switched, and
wherein the count value latch circuit latches the count value excluding the least significant 1 bit in the counter as the delay time when the phase to be selected based on the phase selection signal is switched.

5. The semiconductor device according to claim 2, wherein the timing adjustment circuit individually measures the length of the selection time for each phase during a first transition period where the phase to be selected switches in an earlier phase direction and a second transition period where the phase to be selected switches in a later phase direction and individually retains as the measurement results.

6. The semiconductor device according to claim 5,
wherein the N phases include a first phase, a second phase, and a third phase in order of earlier phase,
wherein, during the first transition period, the timing adjustment circuit is configured to measure the selection time for the second phase specified by the phase selection signal to determine a first delay time based on a first measurement result, and then to output the delayed phase selection signal representing the selection of second phase after the first delay time has elapsed since the phase to be selected by the phase selection signal switches from the third phase to the second phase, and
wherein, during the second transition period, the timing adjustment circuit is configured to measure the selection time for the second phase specified by the phase selection signal to determine a second delay time based on a second measurement result, and then to output the delayed phase selection signal representing the selection of third phase after the second delay time has elapsed since the phase to be selected by the phase selection signal switches from the first phase to the second phase.

7. The semiconductor device according to claim 5, wherein the timing adjustment circuit is configured to output the delayed phase selection signal after a delay time based on the measurement results of the selection time has elapsed, and in parallel, measure the length of the latest selection time to determine the delay time for the next occurrence of the same phase switching.

8. The semiconductor device according to claim 1, wherein the phase judgement circuit is configured to select one of the N phases based on M consecutive phase detection data from the phase detector, where M is an integer of 3 or more.

9. The semiconductor device according to claim 8, wherein the phase judgement circuit includes a majority decision circuit that selects one of the N phases by performing a majority decision on the M consecutive phase detection data.

10. The semiconductor device according to claim 8, wherein the phase detector includes a first flip-flop that outputs first phase detection data by latching the N-phase clock signals at the rising edge of the data signal, and a second flip-flop that outputs second phase detection data by latching the N-phase clock signals at the falling edge of the data signal, and
wherein the M consecutive phase detection data includes the first phase detection data and the second phase detection data.

11. The semiconductor device according to claim 9,
wherein N is an even number,
wherein the phase determination circuit further includes a metastable removal circuit that receives the M consecutive phase detection data from the phase detector, selects one of the N phases for each of the M consecutive phase detection data, and outputs M intermediate phase selection signals representing the phase to be selected,
wherein the majority decision circuit is configured to output the phase selection signal by performing a majority decision on the M intermediate phase selection signals from the metastable removal circuit, and
wherein the metastable removal circuit selects the slowest phase among multiple candidate phases for the correct phase when the number of “H” levels and “L” levels included in the N-bit phase detection data due to metastable are inconsistent.

12. The semiconductor device according to claim 11, wherein the metastable removal circuit represents the correspondence between the N-bit phase detection data and the intermediate phase selection signal and operates based on a predetermined input-output table considering the N-bit phase detection data including the metastable.

13. The semiconductor device according to claim 1,
wherein N is an even number, and
wherein the phase determination circuit includes a metastable removal circuit that selects the slowest phase among multiple candidate phases for the correct phase when the number of “H” levels and “L” levels included in the N-bit phase detection data due to metastable are inconsistent.

14. The semiconductor device according to claim 13, wherein the metastable removal circuit represents the correspondence between the N-bit phase detection data and the phase selection signal and operates based on a predetermined input-output table considering the N-bit phase detection data including the metastable.
